(19) United States
(12) Patent Application Publication
(10) Pub. No.: US 2026/0255763 A1
(43) Pub. Date: Aug. 27, 2026

(54) STRETCHABLE DEVICE AND STRETCHABLE DISPLAY PANEL

(71) Applicant: AUO Corporation, Hsinchu City (TW)

(72) Inventors: Tsung-Ying Ke, Hsinchu City (TW); Yi Hong Shih, Hsinchu City (TW)

(73) Assignee: AUO Corporation, Hsinchu City (TW)

(21) Appl. No.: 19/340,881

(22) Filed: Sep. 26, 2025

(30) Foreign Application Priority Data
Feb. 27, 2025 (TW) 114107228

(51) Int. Cl. H10H 29/854

(52) U.S. Cl. CPC H10H 29/854

(57) ABSTRACT

A stretchable device including a substrate, an electronic structure layer, a first stretchable capping layer and a second stretchable capping layer is provided. The electronic structure layer is disposed on the substrate. The first stretchable capping layer is located between the electronic structure layer and the second stretchable capping layer. A Young's modulus of the second stretchable capping layer is greater than a Young's modulus of the first stretchable capping layer. A stretchable display panel is also provided.

### CROSS-REFERENCE TO RELATED APPLICATION

This application claims the priority benefit of Taiwan application serial no. 114107228, filed on February 27, 2025. The entirety of the above-mentioned patent application is hereby incorporated by reference herein and made a part of this specification.

### BACKGROUND

### TECHNICAL FIELD

The disclosure relates to a stretchable device and a stretchable display panel.

### DESCRIPTION OF RELATED ART

In existing stretchable display devices, only a single layer of over coating (OC) adhesive is disposed on the display structure layer. The OC adhesive is typically a surface-dry material, which, upon curing, has a smooth, non-sticky surface. For stretchable display devices with an overall stretchability ranging from 1% to 5%, the OC adhesive meets the stretching requirements and does not present issues such as the sticking issue of a protective film. However, for stretchable display devices requiring an overall stretchability exceeding 10%, the Young’s modulus of the OC adhesive is too high. Nonetheless, replacing it with an OC adhesive of lower Young’s modulus may result in issues such as the sticking issue of the protective film.

### SUMMARY

A stretchable device and a stretchable display panel, which possess good stretching deformation capability and high yield rates, are provided in the disclosure.

According to an embodiment of the disclosure, a stretchable device is provided, including a substrate, an electronic structure layer, a first stretchable capping layer, and a second stretchable capping layer. The electronic structure layer is disposed on the substrate. The first stretchable capping layer is located between the electronic structure layer and the second stretchable capping layer. A Young's modulus of the second stretchable capping layer is greater than a Young's modulus of the first stretchable capping layer.

According to an embodiment of the disclosure, a stretchable device is provided, including a substrate, an electronic structure layer, a first stretchable capping layer, a second stretchable capping layer, a glue layer, and a stretchable touch layer. The electronic structure layer is disposed on the substrate. The first stretchable capping layer is located between the electronic structure layer and the second stretchable capping layer. The glue layer is located between the stretchable touch layer and the second stretchable capping layer. A Young's modulus of the second stretchable capping layer is greater than a Young's modulus of the first stretchable capping layer.

Based on the above, in the stretchable device and the stretchable display panel provided according to the embodiments of the disclosure, a stretchable capping layer with a smaller Young’s modulus and a stretchable capping layer with a larger Young’s modulus are sequentially disposed on the electronic structure layer. The former can prevent the sticking issue of subsequently applied protective film or prevent the subsequently applied glue layer from experiencing cohesive failure. This significantly enhances the yield rate of the stretchable device while maintaining its good stretching deformation capability.

In order to make the above-mentioned features and advantages of the disclosure comprehensible, embodiments accompanied with drawings are described in detail below.

### BRIEF DESCRIPTION OF THE DRAWINGS

FIG. 1 is a schematic diagram of a stretchable device according to an embodiment of the disclosure.

FIG. 2 shows strain curves of multiple components in a stretchable device according to a comparative example and strain curves of multiple components in a stretchable device according to an embodiment of the disclosure.

### DETAILED DESCRIPTION OF DISCLOSED EMBODIMENTS

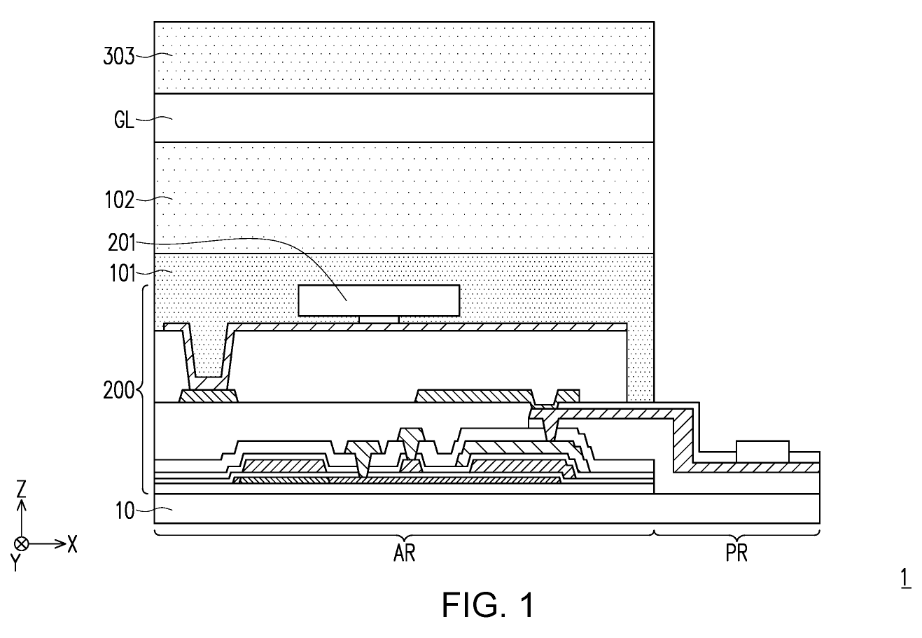

Referring to FIG. 1, FIG. 1 is a schematic diagram of a stretchable device according to an embodiment of the disclosure.

The stretchable device 1 of this embodiment has an active region AR and a peripheral region PR, and includes a substrate 10, an electronic structure layer 200, a stretchable capping layer 101, and a stretchable capping layer 102. The electronic structure layer 200 includes at least one electronic element 201. The electronic structure layer 200, the stretchable capping layer 101, and the stretchable capping layer 102 are sequentially disposed on the substrate 10 along the Z direction. The Young’s modulus of the stretchable capping layer 102 is greater than the Young’s modulus of the stretchable capping layer 101.

It should be noted that, in this embodiment, the stretchable capping layer 101, which is closer to the electronic structure layer 200, has a smaller Young's modulus. This prevents excessive stress in the electronic structure layer 200 when the stretchable device 1 is stretched. In addition, the surface viscosity of the stretchable capping layer 102 with a higher Young’s modulus after curing is lower than the surface viscosity of the stretchable capping layer 101 with a lower Young’s modulus after curing. Therefore, the surface of the stretchable capping layer 102 away from the electronic structure layer 200 is more suitable for the application of a protective film than the surface of the stretchable capping layer 101 away from the electronic structure layer 200. This configuration can prevent the protective film from sticking.

In some embodiments, the Young’s modulus of the stretchable capping layer 102 may fall within a range of 30 MPa to 1 GPa, and/or the Young’s modulus of the stretchable capping layer 101 may fall within a range of 1 MPa to 10 MPa. In some embodiments, the stretchable capping layer 101 has an elongation within a range of 100% to 1500%. In some embodiments, the stretchable capping layer 101 has a maximum elongation, the stretchable capping layer 102 has a maximum elongation, and a ratio of the maximum elongation of the stretchable capping layer 102 to the maximum elongation of the stretchable capping layer 101 is less than 0.7. Accordingly, the stretchable device can have a stretchability greater than 5%, or even greater than 10%, without resulting in excessive stress on the electronic structure layer 200 or sticking issues with the protective film.

Referring to FIG. 1, the stretchable device 1 of this embodiment may further include a glue layer GL, which has a Young’s modulus less than the Young’s modulus of the stretchable capping layer 101 and falls within the range of 0.01 MPa to 1 MPa. In a comparative example, the stretchable device 1 does not include the stretchable capping layer 102, and the glue layer GL is disposed on the surface of the stretchable capping layer 101 away from the electronic structure layer 200. When the stretchable device 1 of this comparative example is stretched, the glue layer GL thereon is prone to cohesive failure due to the lower Young’s modulus of the stretchable capping layer 101. In contrast, in the embodiment shown in FIG. 1, since the stretchable capping layer 102 is located between the glue layer GL and the stretchable capping layer 101, the stretchable capping layer 102 having a higher Young’s modulus can prevent the occurrence of cohesive failure in the glue layer GL when the stretchable device 1 is stretched.

As shown in FIG. 1, the stretchable device 1 of this embodiment may further include a stretchable layer 303, in which the glue layer GL is configured to adhere the stretchable layer 303 and the stretchable capping layer 102. In some embodiments, the stretchable layer 303 is a protective film, but not limited thereto.

In some embodiments, the stretchable device 1 may be a stretchable display panel, the electronic element 201 may be a light-emitting diode, the glue layer GL may be a clear optical adhesive layer, and the stretchable layer 303 may be a stretchable touch layer, but not limited thereto.

Also referring to FIG. 1, in some embodiments, the stretchable device 1 may further satisfy the conditional formula E2*H2>3*E1*H1, where H1 is the maximum thickness of the stretchable capping layer 101 in the normal direction (Z direction) of the substrate 10, H2 is the maximum thickness of the stretchable capping layer 102 in the Z direction, E1 is the Young’s modulus of the stretchable capping layer 101, and E2 is the Young’s modulus of the stretchable capping layer 102. Accordingly, the stretchable capping layer 102 may have sufficient stiffness to drive the stretchable device 1 to rebound (or retract) after deformation.

It should be noted that, in some embodiments, the stretchable device 1 may have a stretchable region and a non-stretchable region. In the stretchable region of the stretchable device 1, the stretchable capping layer 102 may be disposed on a side of the stretchable capping layer 101 away from the substrate 10 as shown in FIG. 1. In the non-stretchable region of the stretchable device 1, the substrate 10 may have both the stretchable capping layer 101 and the stretchable capping layer 102, or only one of the stretchable capping layer 101 and the stretchable capping layer 102.

Also referring to FIG. 1, in some embodiments, the stretchable device 1 is a stretchable display panel, the electronic element 201 is a light-emitting diode 201, and the refractive index of the glue layer GL is greater than or equal to the refractive index of the stretchable capping layer 102. Consequently, this configuration prevents total internal reflection of light emitted by the light-emitting diode 201 when entering the glue layer GL from the stretchable capping layer 102. In some embodiments, the refractive index of the stretchable capping layer 102 is greater than or equal to the refractive index of the stretchable capping layer 101. Consequently, this configuration prevents total internal reflection of light emitted by the light-emitting diode 201 when entering the stretchable capping layer 102 from the stretchable capping layer 101.

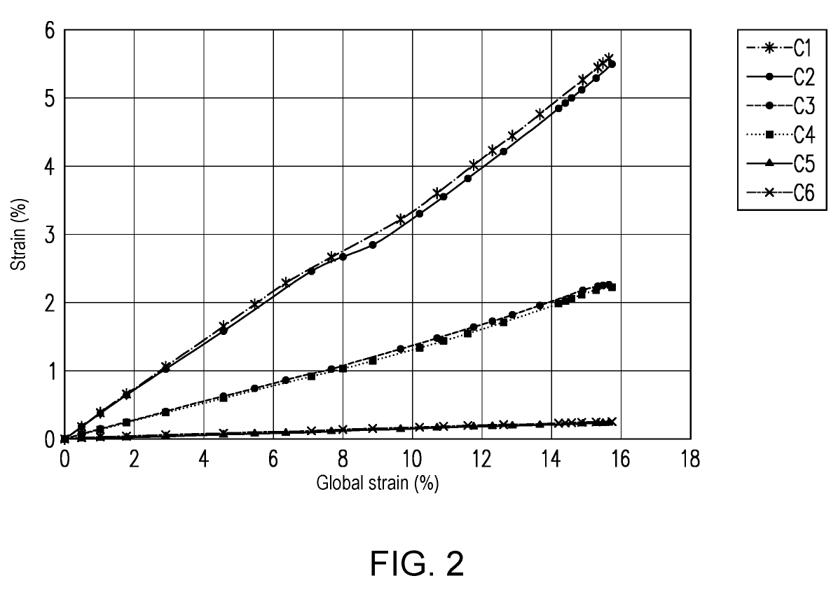

Referring to FIG. 2, FIG. 2 shows strain curves of multiple components in a stretchable device according to a comparative example and strain curves of multiple components in a stretchable device according to an embodiment of the disclosure, in which the stretchable device of the comparative example and the stretchable device of the embodiment of the disclosure are both stretchable display panels. Curve C1, curve C3 and curve C5 in FIG. 2 are strain curves of the polymer wiring, the metal wiring and the island structure in the stretchable device of the comparative example, respectively. Curve C2, curve C4 and curve C6 are strain curves of the polymer wiring, the metal wiring and the island structure in the stretchable device of the embodiment of the disclosure, respectively. The stretchable device according to the comparative example is provided with only the stretchable capping layer 101. The stretchable device according to an embodiment of the disclosure includes both the stretchable capping layer 101 and the stretchable capping layer 102, and has a structure as shown in FIG. 1. It can be seen that the strain curves of the multiple components in the stretchable device according to the comparative example and the strain curves of the multiple components in the stretchable device according to the embodiment of the disclosure are consistent. That is to say, by disposing the stretchable capping layer 102 on the stretchable capping layer 101, the stretchable device can still maintain good stretching deformation capability.

To sum up, in the stretchable device and the stretchable display panel provided according to the embodiments of the disclosure, a stretchable capping layer with a smaller Young’s modulus and a stretchable capping layer with a larger Young’s modulus are sequentially disposed on the electronic structure layer. The former can prevent the sticking issue of subsequently applied protective film or prevent the subsequently applied glue layer from experiencing cohesive failure. This significantly enhances the yield rate of the stretchable device while maintaining its good stretching deformation capability.

What is claimed is:

1. A stretchable device, comprising:
a substrate;
an electronic structure layer, disposed on the substrate;
a first stretchable capping layer; and
a second stretchable capping layer, wherein the first stretchable capping layer is located between the electronic structure layer and the second stretchable capping layer, wherein
a Young's modulus of the second stretchable capping layer is greater than a Young's modulus of the first stretchable capping layer.

2. The stretchable device according to claim 1, wherein the stretchable device has a stretchability greater than 5%.

3. The stretchable device according to claim 1, wherein the stretchable device further satisfies a conditional formula E2*H2>3*E1*H1, H1 is a maximum thickness of the first stretchable capping layer in a normal direction of the substrate, H2 is a maximum thickness of the second stretchable capping layer in the normal direction, E1 is the Young's modulus of the first stretchable capping layer, and E2 is the Young's modulus of the second stretchable capping layer.

4. The stretchable device according to claim 1, wherein the first stretchable capping layer has a first maximum elongation, the second stretchable capping layer has a second maximum elongation, and a ratio of the second maximum elongation to the first maximum elongation is less than 0.7.

5. The stretchable device according to claim 1, wherein the first stretchable capping layer has an elongation within a range of 100% to 1500%.

6. The stretchable device according to claim 1, wherein the Young's modulus of the second stretchable capping layer falls within a range of 30 MPa to 1 GPa.

7. The stretchable device according to claim 1, wherein the Young's modulus of the first stretchable capping layer falls within a range of 1 MPa to 10 MPa.

8. The stretchable device according to claim 1, further comprising a glue layer, wherein the second stretchable capping layer is located between the glue layer and the first stretchable capping layer.

9. The stretchable device according to claim 1, further comprising a third stretchable capping layer and a glue layer, wherein the glue layer is located between the third stretchable capping layer and the second stretchable capping layer.

10. The stretchable device according to claim 9, wherein a Young's modulus of the glue layer is less than the Young's modulus of the first stretchable capping layer.

11. The stretchable device according to claim 9, wherein a Young's modulus of the glue layer falls within a range of 0.01 MPa to 1 MPa.

12. The stretchable device according to claim 9, wherein a refractive index of the glue layer is greater than or equal to a refractive index of the second stretchable capping layer.

13. The stretchable device according to claim 12, wherein the refractive index of the second stretchable capping layer is greater than or equal to a refractive index of the first stretchable capping layer.

14. A stretchable display panel, comprising:
a substrate;
an electronic structure layer, disposed on the substrate;
a first stretchable capping layer;
a second stretchable capping layer, wherein the first stretchable capping layer is located between the electronic structure layer and the second stretchable capping layer;
a glue layer; and
a stretchable touch layer, wherein the glue layer is located between the stretchable touch layer and the second stretchable capping layer,
wherein a Young's modulus of the second stretchable capping layer is greater than a Young's modulus of the first stretchable capping layer.

15. The stretchable display panel according to claim 14, wherein a Young's modulus of the glue layer is less than the Young's modulus of the first stretchable capping layer.

16. The stretchable display panel according to claim 14, wherein a Young's modulus of the glue layer falls within a range of 0.01 MPa to 1 MPa.

17. The stretchable display panel according to claim 14, wherein a refractive index of the glue layer is greater than or equal to a refractive index of the second stretchable capping layer.

18. The stretchable display panel according to claim 17, wherein the refractive index of the second stretchable capping layer is greater than or equal to a refractive index of the first stretchable capping layer.
